(19) United States
(12) Patent Application Publication
(10) Pub. No.: US 2026/0019054 A1
(43) Pub. Date: Jan. 15, 2026

(54) BETA VARIATION INSENSITIVE GAIN CONTROL CIRCUIT FOR CROSS-COUPLED DIFFERENTIAL PAIRS

(71) Applicant: MACOM Technology Solutions Holdings, Inc., Lowell, MA (US)

(72) Inventors: Ariel Leonardo VERA VILLARROEL, Lowell, MA (US); Abdelrahman H. AHMED, Lowell, MA (US)

(21) Appl. No.: 18/771,241

(22) Filed: Jul. 12, 2024

(51) Int. Cl. H03G 3/30; H01L 27/082; H03G 1/00

(52) U.S. Cl. CPC H03G 3/3042; H03G 1/0023; H10D 84/645

(57) ABSTRACT

Circuits, semiconductor devices, and systems are provided. An illustrative circuit includes a first pair of transistors cross-coupled with a second pair of transistors. The circuit may further include a gain control circuit coupled with the first pair of transistors and the second pair of transistors, where the gain control circuit provides an error compensation for a beta variation effect in at least one of the first pair of transistors and the second pair of transistors.

### FIELD OF THE DISCLOSURE

The present disclosure is generally directed toward circuits and, in particular, toward amplifier circuits, driver circuits, and gain control circuits.

### BACKGROUND

Signal processing in the electrical domain requires gain blocks whose gain can be controlled. Two cross-coupled differential pairs offer a possible circuit topology for gain control circuits. Such circuits are also capable of inverting the signal polarity. Gain control using this topology may be implemented with transistors.

When gain control is implemented using cross-coupled differential pairs of Bipolar Junction Transistors (BJTs), the gain and linearity of the circuit becomes beta-variation-dependent. Beta represents a circuit design parameter and is the BJTs current gain. Beta is the ratio of each transistor's collector current to its base current and has no units because it's a fixed ratio of two currents. Beta can affect the functionality of a BJT and is dependent on quiescent collector current density as well as temperature.

### SUMMARY

Embodiments of the present disclosure contemplate solutions to the above-noted challenges. In particular, a gain control circuit is provided for cross-coupled differential pairs that reduces the beta variation effect in the amplified signal while maintaining the signal integrity. In some embodiments, the cross-coupled differential pairs of transistors may include four transistors provided in a cross-coupled configuration. A high frequency (HF) input signal may include a differential current fed to the nodes with shorted emitters. The collectors of the transistors may be cross-coupled and provide the output current. Base terminals of the transistors are connected such the voltage difference between them sets the signal gain. The gain control circuit disclosed herein may include the correction required due to the increase of base-current of transistors due to process variation and/or stress on the devices.

In some embodiments, a circuit is provided that includes: a first pair of transistors cross-coupled with a second pair of transistors; and a gain control circuit coupled with the first pair of transistors and the second pair of transistors, where the gain control circuit provides an error compensation for a beta variation effect in at least one of the first pair of transistors and the second pair of transistors.

According to at least some aspects, the gain control circuit provides the error compensation for the beta variation effect in both the first pair of transistors and the second pair of transistors.

According to at least some aspects, the gain control circuit maintains a signal integrity passing through the first pair of transistors and the second pair of transistors.

According to at least some aspects, the first pair of transistors comprises a first transistor and a second transistor, wherein the second pair of transistors comprises a third transistor and a fourth transistor, wherein a collector terminal of the first transistor is coupled directly to a collector terminal of the third transistor, wherein a collector terminal of the second transistor is coupled directly to a collector terminal of the fourth transistor, wherein a base terminal of the first transistor is coupled directly to a base terminal of the fourth transistor, wherein a base terminal of the second transistor is coupled directly to a base terminal of the third transistor, wherein an emitter terminal of the first transistor is coupled directly to an emitter terminal of the second transistor, wherein an emitter terminal of the third transistor is coupled directly to an emitter terminal of the fourth transistor, wherein the emitter terminals of the first and second transistors receive a first aspect of an input signal, wherein the emitter terminals of the third and fourth transistors receive a second aspect of the input signal, wherein the collector terminals of the first and third transistors provide a first aspect of an output signal, and wherein the collector terminals of the second and fourth transistors provide a second aspect of the output signal.

According to at least some aspects, the gain control circuit is coupled across a first control node between the base terminals of the first and fourth transistors and a second control node between the base terminals of the second and third transistors.

According to at least some aspects, the base terminals of the first, second, third, and fourth transistors are connected such that a voltage difference therebetween sets a gain of the output signal.

According to at least some aspects, the gain control circuit includes a first gain control transistor and a second gain control transistor that receive a first control current and a second control current respectively, wherein a base terminal of the first gain control transistor is coupled to the first control node, and wherein a base terminal of the second gain control transistor is coupled to the second control node.

According to at least some aspects, the gain control circuit further comprises a current control subcircuit that generates the first control current and the second control current.

According to at least some aspects, the current control subcircuit comprises a current source that feeds a differential pair of transistors, wherein a first transistor in the differential pair of transistors receives a variable voltage at a gate thereof, wherein the variable voltage sets a gain voltage for the gain control circuit, and wherein a second transistor in the differential pair of transistors receives a reference voltage at a gate thereof.

According to at least some aspects, the current source includes a first additional transistor, a second additional transistor, a third additional transistor diode connected, and a fourth additional transistor in a common-collector configuration biased via a current source, and wherein a base of the fourth additional transistor is connected to a node between the gate of the second additional transistor and a gate of the additional third transistor.

According to at least some aspects, the second transistor copies a base current of the fourth transistor to the differential pair of transistors such that when the base current changes, the current source changes proportionally.

In some embodiments, a semiconductor device is provided that includes: cross-coupled differential pairs of transistors; and a gain control circuit coupled with the cross-coupled differential pairs of transistors, where the gain control circuit provides an error compensation for a beta variation effect in the cross-coupled differential pairs of transistors.

According to at least some aspects, the cross-coupled differential pairs of transistors inverts a polarity of an input signal provided thereto.

According to at least some aspects, the gain control circuit maintains a signal integrity passing through the cross-coupled differential pairs of transistors.

According to at least some aspects, the cross-coupled differential pairs of transistors comprises a first transistor, a second transistor, a third transistor, and a fourth transistor.

According to at least some aspects, a collector terminal of the first transistor is coupled directly to a collector terminal of the third transistor, wherein a collector terminal of the second transistor is coupled directly to a collector terminal of the fourth transistor, wherein a base terminal of the first transistor is coupled directly to a base terminal of the fourth transistor, wherein a base terminal of the second transistor is coupled directly to a base terminal of the third transistor, wherein an emitter terminal of the first transistor is coupled directly to an emitter terminal of the second transistor, wherein an emitter terminal of the third transistor is coupled directly to an emitter terminal of the fourth transistor, wherein the emitter terminals of the first and second transistors receive a first aspect of an input signal, wherein the emitter terminals of the third and fourth transistors receive a second aspect of the input signal, wherein the collector terminals of the first and third transistors provide a first aspect of an output signal, and wherein the collector terminals of the second and fourth transistors provide a second aspect of the output signal.

According to at least some aspects, the gain control circuit is coupled across a first control node between the base terminals of the first and fourth transistors and a second control node between the base terminals of the second and third transistors.

According to at least some aspects, the gain control circuit comprises a first gain control transistor and a second gain control transistor that receive a first control current and a second control current respectively, wherein a base terminal of the first gain control transistor is coupled to the first control node, and wherein a base terminal of the second gain control transistor is coupled to the second control node.

According to at least some aspects, the gain control circuit further comprises a current control subcircuit that generates the first control current and the second control current, wherein the current control subcircuit comprises a current source that feeds a differential pair of transistors, wherein a first transistor in the differential pair of transistors receives a variable voltage at a gate thereof, wherein the variable voltage sets a gain voltage for the gain control circuit, and wherein a second transistor in the differential pair of transistors receives a reference voltage at a gate thereof.

In some embodiments, a system is provided that includes: a gain block including cross-coupled differential pairs of transistors; and a gain control circuit coupled with the cross-coupled differential pairs of transistors, where the gain control circuit provides an error compensation for a beta variation effect in the cross-coupled differential pairs of transistors.

The preceding is a simplified summary to provide a basic understanding of some aspects and embodiments described herein. This summary is not an extensive overview of the disclosed subject matter. It is neither intended to identify key nor critical elements of the disclosure nor delineate the scope thereof. The summary is provided to present some concepts in a simplified form as a prelude to the more detailed description that is presented later.

### BRIEF DESCRIPTION OF THE DRAWINGS

The present disclosure is described in conjunction with the appended figures, which are not necessarily drawn to scale:

FIG. 1 is a block diagram illustrating a communication system according to at least some embodiments of the present disclosure;

FIG. 2 is a block diagram illustrating a gain control circuit interacting with cross-coupled differential pairs of transistors according to at least some embodiments of the present disclosure;

FIG. 3 illustrates details of a gain control circuit according to at least some embodiments of the present disclosure;

FIG. 4 illustrates current control circuit used in connection with a gain control circuit according to at least some embodiments of the present disclosure;

FIG. 5 illustrates normalized gain versus the normalized gain control voltage for a circuit according to at least some embodiments of the present disclosure;

FIG. 6 illustrates a normalized high frequency output signal over time according to at least some embodiments of the present disclosure;

FIG. 7 illustrates a Total Harmonic Distortion (THD) versus a cross-coupled output signal according to at least some embodiments of the present disclosure; and

FIG. 8 illustrates a method of configuring and operating a gain control circuit according to at least some embodiments of the present disclosure.

### DETAILED DESCRIPTION

It is with respect to the above-noted challenges that embodiments of the present disclosure were contemplated. In particular, a system, circuits, and method of operating such circuits are provided that solve the drawbacks associated with existing amplifier circuits, driver circuits, and/or equalizer circuits.

While embodiments of the present disclosure will primarily be described in connection with amplifier circuits used in high-bandwidth applications, it should be appreciated that embodiments of the present disclosure are not so limited. Furthermore, while embodiments of the present disclosure are contemplated for use in connection with high-speed communications over copper or fiber, it should be appreciated that the claims are not limited to high speed electrical and optical or EO communications. Indeed, the biasing and crossing control circuit(s) depicted and described herein may be utilized in any number of applications utilizing an amplifier (e.g., transmitter applications, receiver applications, filtering applications, etc.). Example embodiments of the present disclosure will be described in connection with broadband applications, but it should be appreciated that the circuit(s) depicted and described herein can be utilized in other non-broadband applications.

Various aspects of the present disclosure will be described herein with reference to drawings that are schematic illustrations of idealized configurations. It should be appreciated that while particular circuit configurations and circuit elements are described herein, embodiments of the present disclosure are not limited to the illustrative circuit configurations and/or circuit elements depicted and described herein. Specifically, it should be appreciated that circuit elements of a particular type or function may be replaced with one or multiple other circuit elements to achieve a similar function without departing from the scope of the present disclosure.

It should also be appreciated that the embodiments described herein may be implemented in any number of form factors. Specifically, the entirety of the circuits disclosed herein may be implemented in silicon as a fully-integrated solution (e.g., as a single Integrated Circuit (IC) chip or multiple IC chips) or they may be implemented as discrete components connected to a Printed Circuit Board (PCB). For example, circuit components depicted and described herein may be provided on a single piece of silicon (e.g., a single semiconductor die), on multiple pieces of silicon, on a PCB, or combinations thereof.

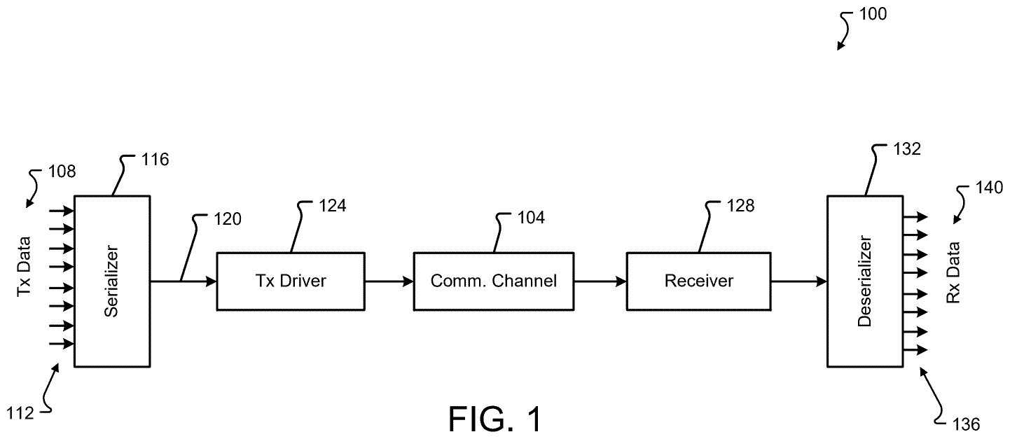

Referring initially to FIG. 1, an illustrative communication system 100 will be described in accordance with at least some embodiments of the present disclosure. The system 100 represents but one possible environment of use of the innovation(s) disclosed herein. As shown, data to be transmitted, referred to as transmit data 108 is provided over two or more parallel paths 112 to a serializer 116. The serializer 116 converts the data received from the two or more parallel paths 112 to a serial stream of data on serial data path 120. The serial stream of data is presented to a transmitter driver 124 which amplifies the signal to a level suitable for transmission over a communication channel 104.

The communication channel 104 may include or correspond to any suitable type of communication channel, such as a channel used for high-speed data transmission. The communication channel 104 may correspond to or include one or more optical fibers. The communication channel 104 may alternatively or additionally correspond to or include one or more electrically-conductive lines such as PCB traces, coaxial cables, connectors, or the like. Thus, the data transmitted by the transmitter driver 124 may include an optical signal and/or electrical signal. In one embodiment, the communication channel 104 is length of optical fiber, which may span in length from few meters to tens of kilometers. However, the method and apparatus disclosed herein may be used for channels of any length or type, such as but not limited to, fiber channels, circuit board traces, coaxial cables, or wired channels, all of which may be any suitable length.

After passing through the communication channel 104, the data is presented to a receiver circuit 128. The receiver circuit 128 may include one or more gain stages. The transmitter driver 124 may include one or more drivers. The transmitter driver 124 and/or receiver circuit 128 may be provided with one or more amplifier circuits comprising one or more biasing and crossing control circuits as depicted and described herein. The transmitter driver 124 and/or receiver circuit 128 may also include one or more equalizer circuits. The equalizer(s) may be configured to reduce the signal attenuating effects of the communication channel 104.

After equalization, the data is provided to a deserializer 132 which converts the serial data stream to a parallel data path on the two or more data paths 136. The data output by the deserializer may be regarded as received data 140 that can be processed by a communication device that includes the receiver circuit 128 and deserializer 132.

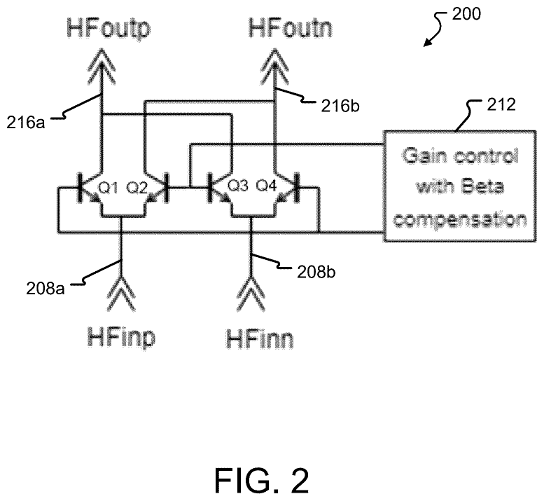

Referring now to FIGS. 2-4, various types of circuit 200 configurations that may be used in connection with a communication system 100 will be described in accordance with at least some embodiments of the present disclosure. As a non-limiting example, the circuit 200 may be provided as part of the transmitter driver 124 that is used to amplify a signal prior to transmission of the signal on the communication channel 104. It may also be possible to include the circuit 200 as part of the receiver circuit 128 to amplify a signal received over the communication channel 104.

FIG. 2 illustrates an example circuit 200 having four transistors Q1, Q2, Q3, Q4. The transistors Q1-Q4 are provided in a cross-coupled configuration. An input signal is provided to the circuit 200 as a high frequency (HF) input signal comprising a differential current. Specifically, a first aspect of the input signal HFinp is provided to emitter terminals of the first and second transistors Q1, Q2. A second aspect of the input signal HFinn is provided to emitter terminals of the third and fourth transistors Q3, Q4. In other words, the input signal HFinp and HFinn, in some embodiments, corresponds to a differential current fed to the input nodes of the transistors with shorted emitters. A first input node 208a that receives the first aspect of the input signal HFinp may correspond to the node at which emitters of the first and second transistors Q1, Q2 are connected. A second input node 208b that receives the second aspect of the input signal HFinn may correspond to the node at which emitters of the third and fourth transistors Q3, Q4 are connected.

The collectors of the transistors Q1-Q4 are cross-coupled and provide the output current HFoutp, HFoutn. Specifically, the collector terminals of the first and third transistors Q1, Q3 may be coupled together and provide a first aspect of the output signal HFoutp. The collector terminals of the second and fourth transistors Q2, Q4 may be coupled together and provide a second aspect of the output signal HFoutn. Base terminals of the transistors Q1-Q4 are connected such the voltage difference between them sets the signal gain. In the depicted configuration, the collector terminals of the first and third transistors Q1, Q3 are directly connected to one another at a first output node 216a and provide the first aspect of the output signal HFoutp. The collector terminals of the second and fourth transistors Q2, Q4 are directly connected to one another at a second output node 216b and provide the second aspect of the output signal HFoutn. In some embodiments, the cross-coupled different pairs of transistors Q1-Q4 inverts a polarity of the input signal provided thereto.

As will be described in further detail, the proposed solution presents a gain control circuit 212 that includes the correction required due to the increase of base-current of transistors Q1-Q4 due to process variation and/or stress on the devices. In some embodiments, the gain control circuit 212 may be configured to provide an error compensation for a beta variation effect in at least one of the transistors Q1-Q4. In some embodiments, the gain control circuit 212 may be configured to provide an error compensation for the beta variation effect in all of the transistors Q1-Q4 while maintaining a signal integrity between the input signal and the output signal.

The gain control circuit 212 is shown to connect across the cross-coupled transistors Q1-Q4. Specifically, but without limitation, the gain control circuit 212 may be coupled across a first control node between the base terminals of the first and fourth transistors Q1, Q4 and a second control node between the base terminals of the second and third transistors Q2, Q3.

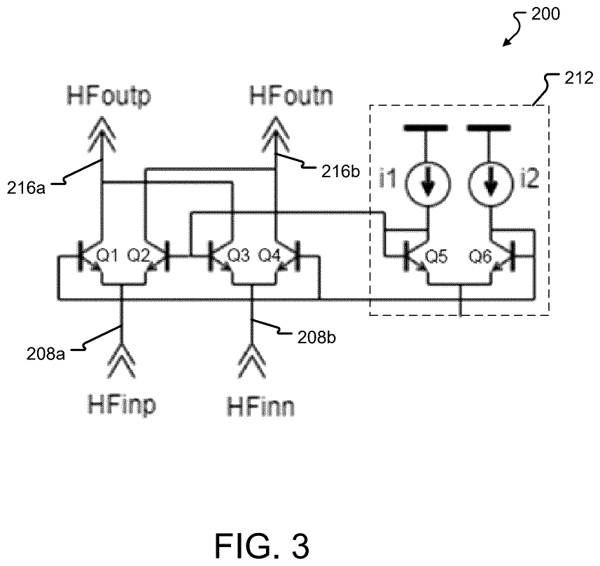

With reference now to FIG. 3, one possible implementation of a gain control circuit 212 will be described in accordance with at least some embodiments of the present disclosure. The gain control circuit 212 is shown to include a first control current i1 and a second control current i2. The gain control circuit 212 is also shown to include a first gain control transistor Q5 and a second gain control transistor Q6. The first gain control transistor Q5 receives the first control current i1 whereas the second gain control transistor Q6 receives the second control current i2.

In the depicted embodiment, the base terminal of the first gain control transistor Q5 is coupled to the first control node and the base terminal of the second gain control transistor Q6 is coupled to the second control node. In such a configuration, the gain control transistors Q5 and Q6 have the bases connected to their collectors (e.g., as a diode connected transistor). Each of the diode connected transistors is connected to a control network. With this solution, control currents i1 and i2 are used to set the gain of circuit 200. An error in the gain setting is generated due to the base current of all transistors connected to these current sources. Therefore, both currents i1, i2 implement a correction factor to be able to sustain the gain setting under base-current variation, which is due to beta degradation, a process variation and/or stress related effect.

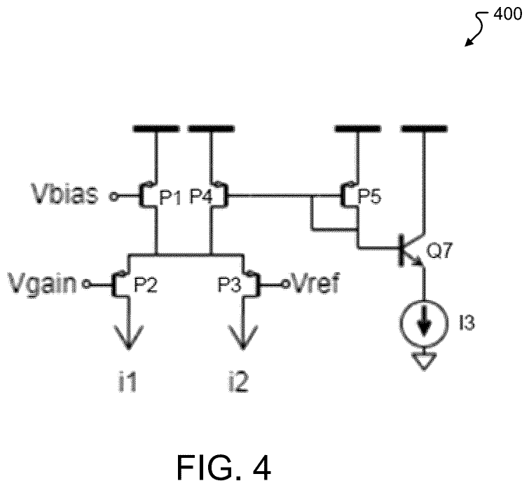

Referring now to FIG. 4, additional details of the gain control circuit 212 will be described in accordance with at least some embodiments of the present disclosure. In particular, the gain control circuit 212 may further include a current control subcircuit 400 that is used to generate the control currents i1, i2.

In the depicted embodiment, the current control subcircuit 400 is shown to include a first current source transistor P1 that feeds a differential pair of transistors P2, P3. The gate of one of the transistors P3 in the differential pair of transistors may receive a reference voltage Vref, while the voltage at the gate of the other transistor P2 in the differential pair of transistors is a variable voltage that sets the gain Vgain. In some embodiments, the variable voltage that sets the gain Vgain may be controlled from outside the current control subcircuit 400 or from within the current control subcircuit 400. More specifically, the variable voltage that sets the gain Vgain may be controlled outside of the semiconductor device including the current control subcircuit 400 or may be controlled via an integrated DAC within the semiconductor device.

The current control subcircuit 400 is further shown to include a second additional transistor P4, a third additional transistor P5, and a fourth additional transistor Q7. To correct beta variation effects, the fourth additional transistor Q7 is biased at a similar current density of transistors Q1, Q2, Q3, and Q4. The base current of the fourth additional transistor Q7 is connected to the third additional transistor P5, which is shown to be diode-connected.

The second additional transistor P4 may have the same source and gate voltage as the third transistor P5; therefore, the second additional transistor P4 may copy the base current of the fourth additional transistor Q7 to the differential pair of transistors P2, P3. This configuration may cause the current controlling the gain to increase proportionally when the base current of the fourth transistor Q7 increases.

Performance of the current control subcircuit 400 can be further improved with respect to power consumption by scaling down the fourth additional transistor Q7 with respect to the transistors Q1, Q2, Q3, and Q4 and by scaling-up the second additional transistor P4 to ensure proper variation.

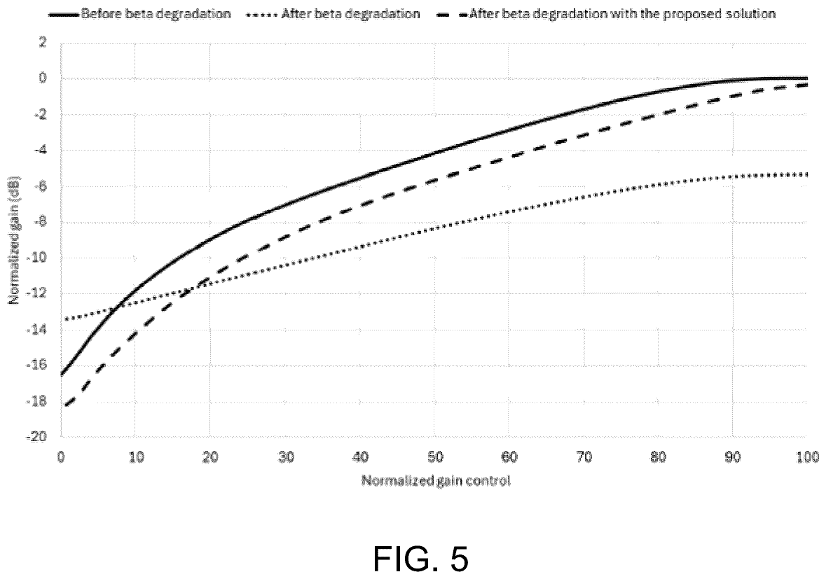

With reference now to FIG. 5, the normalized gain versus the normalized control voltage of the circuit 200 will be described in accordance with at least some embodiments of the present disclosure. Specifically, the solid line shows a performance of the gain control circuit 212 across gain settings. When beta varies within the process variation, the base currents of the transistors in the quad (e.g., Q1, Q2, Q3, Q4) increase, changing the performance of the gain over gain settings (dotted line). Under such conditions, the maximum gain is not attainable, and the overall gain range is reduced.

Adding the beta correction in accordance with embodiments of the present disclosure (e.g., by implementing a gain control circuit 212) allows the ability to obtain the maximum gain while maintaining similar gain control range (dashed line).

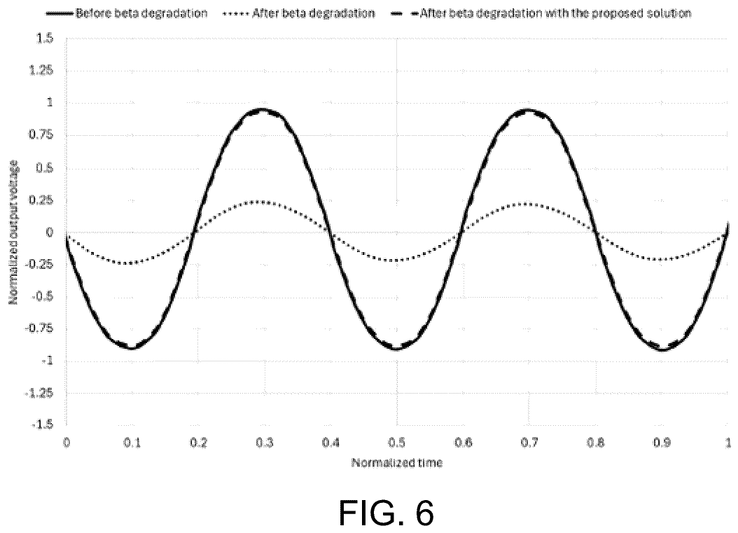

Referring now to FIG. 6, the normalized high frequency output signal versus normalized time is shown. In normal operation, the input signal is amplified with the required integrity at the circuit output (solid line). In the presence of beta degradation, the gain is reduced, as shown in the output signal (dotted line).

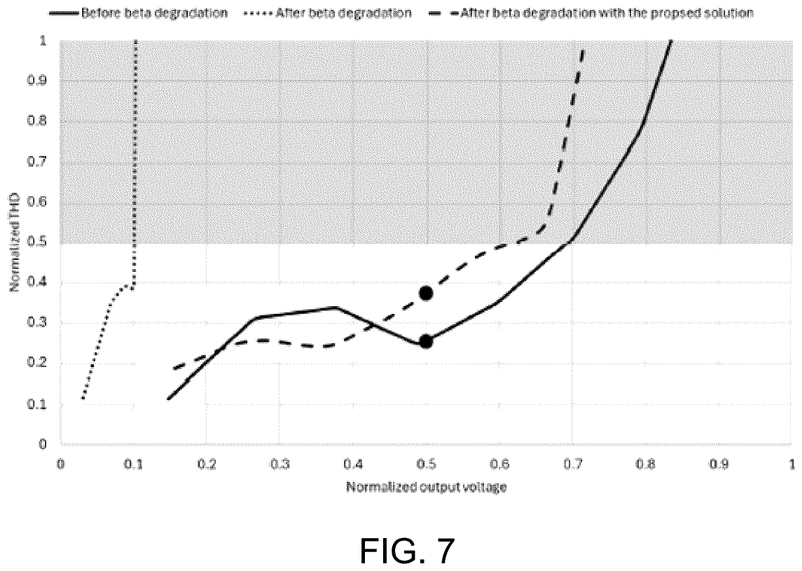

Utilization of the proposed gain control solution recovers the gain, and the amplified signal is again similar to the target (dashed line). It should be noted that increasing the input signal, when beta degradation is present and the proposed solution is not implemented, will not produce the target output, given that the cross-coupled circuit is limited in the maximum output as shown with reference to FIG. 7.

FIG. 7 illustrates the THD versus the cross-coupled output signal HFoutp, HFoutn. Specifically, FIG. 7 shows that the output signal HFoutp, HFoutn and its harmonic content as the input signal HFinp, HFinn is increased.

These results were obtained at a maximum gain setting. Without degradation the 0.5 target output signal is achieved within an acceptable THD. When beta degradation is present, the target output signal is not achieved even when the input signal is increased (as shown by the fast increase of THD). The target output is again achievable when a gain control circuit 212 is implemented in accordance with embodiments of the present disclosure.

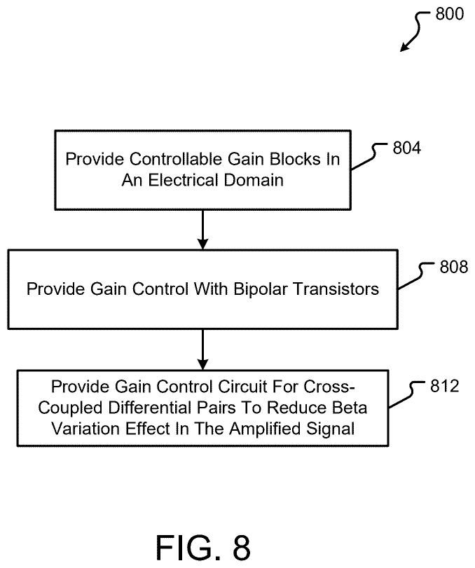

Referring now to FIG. 8, a method 800 of operating a circuit 200 will be described in accordance with at least some embodiments of the present disclosure. The method 800 begins by providing one or more controllable gain blocks in an electrical domain (step 804). The gain block(s) may then be subjected to gain control. Specifically, but without limitation, gain control may be provided for the gain blocks using one or more bipolar transistors (step 808). In some embodiments, the gain block may include cross-coupled different pairs of transistors.

The method 800 then continues by providing a gain control circuit 212 for the cross-coupled differential pairs of transistors to reduce beta variation effects in the amplified signal of the gain block (step 812).

Specific details were given in the description to provide a thorough understanding of the embodiments. However, it will be understood by one of ordinary skill in the art that the embodiments may be practiced without these specific details. In other instances, well-known circuits, processes, algorithms, structures, and techniques may be shown without unnecessary detail in order to avoid obscuring the embodiments.

While illustrative embodiments of the disclosure have been described in detail herein, it is to be understood that the inventive concepts may be otherwise variously embodied and employed, and that the appended claims are intended to be construed to include such variations, except as limited by the prior art.

What is claimed is:

1. A circuit, comprising:
a first pair of transistors cross-coupled with a second pair of transistors; and
a gain control circuit coupled with the first pair of transistors and the second pair of transistors, wherein the gain control circuit provides an error compensation for a beta variation effect in at least one of the first pair of transistors and the second pair of transistors.

2. The circuit of claim 1, wherein the gain control circuit provides the error compensation for the beta variation effect in both the first pair of transistors and the second pair of transistors.

3. The circuit of claim 2, wherein the gain control circuit maintains a signal integrity passing through the first pair of transistors and the second pair of transistors.

4. The circuit of claim 1, wherein the first pair of transistors comprises a first transistor and a second transistor, wherein the second pair of transistors comprises a third transistor and a fourth transistor, wherein a collector terminal of the first transistor is coupled directly to a collector terminal of the third transistor, wherein a collector terminal of the second transistor is coupled directly to a collector terminal of the fourth transistor, wherein a base terminal of the first transistor is coupled directly to a base terminal of the fourth transistor, wherein a base terminal of the second transistor is coupled directly to a base terminal of the third transistor, wherein an emitter terminal of the first transistor is coupled directly to an emitter terminal of the second transistor, wherein an emitter terminal of the third transistor is coupled directly to an emitter terminal of the fourth transistor, wherein the emitter terminals of the first and second transistors receive a first aspect of an input signal, wherein the emitter terminals of the third and fourth transistors receive a second aspect of the input signal, wherein the collector terminals of the first and third transistors provide a first aspect of an output signal, and wherein the collector terminals of the second and fourth transistors provide a second aspect of the output signal.

5. The circuit of claim 4, wherein the gain control circuit is coupled across a first control node between the base terminals of the first and fourth transistors and a second control node between the base terminals of the second and third transistors.

6. The circuit of claim 5, wherein the base terminals of the first, second, third, and fourth transistors are connected such that a voltage difference therebetween sets a gain of the output signal.

7. The circuit of claim 5, wherein the gain control circuit comprises a first gain control transistor and a second gain control transistor that receive a first control current and a second control current respectively, wherein a base terminal of the first gain control transistor is coupled to the first control node, and wherein a base terminal of the second gain control transistor is coupled to the second control node.

8. The circuit of claim 7, wherein the gain control circuit further comprises a current control subcircuit that generates the first control current and the second control current.

9. The circuit of claim 8, wherein the current control subcircuit comprises a current source that feeds a differential pair of transistors, wherein a first transistor in the differential pair of transistors receives a variable voltage at a gate thereof, wherein the variable voltage sets a gain voltage for the gain control circuit, and wherein a second transistor in the differential pair of transistors receives a reference voltage at a gate thereof.

10. The circuit of claim 9, wherein the current source includes a first additional transistor, a second additional transistor, a third additional transistor diode connected, and a fourth additional transistor in a common-collector configuration biased via a current source, and wherein a base of the fourth additional transistor is connected to a node between a gate of the second additional transistor and a gate of the third additional transistor.

11. The circuit of claim 10, wherein the second transistor copies a base current of the fourth transistor to the differential pair of transistors such that when the base current changes, the current source changes proportionally.

12. A semiconductor device, comprising:
cross-coupled differential pair of transistors; and
a gain control circuit coupled with the cross-coupled differential pairs of transistors, wherein the gain control circuit provides an error compensation for a beta variation effect in the cross-coupled differential pairs of transistors.

13. The semiconductor device of claim 12, wherein the cross-coupled differential pairs of transistors inverts a polarity of an input signal provided thereto.

14. The semiconductor device of claim 12, wherein the gain control circuit maintains a signal integrity passing through the cross-coupled differential pairs of transistors.

15. The semiconductor device of claim 12, wherein the cross-coupled differential pairs of transistors comprises a first transistor, a second transistor, a third transistor, and a fourth transistor.

16. The semiconductor device of claim 15, wherein a collector terminal of the first transistor is coupled directly to a collector terminal of the third transistor, wherein a collector terminal of the second transistor is coupled directly to a collector terminal of the fourth transistor, wherein a base terminal of the first transistor is coupled directly to a base terminal of the fourth transistor, wherein a base terminal of the second transistor is coupled directly to a base terminal of the third transistor, wherein an emitter terminal of the first transistor is coupled directly to an emitter terminal of the second transistor, wherein an emitter terminal of the third transistor is coupled directly to an emitter terminal of the fourth transistor, wherein the emitter terminals of the first and second transistors receive a first aspect of an input signal, wherein the emitter terminals of the third and fourth transistors receive a second aspect of the input signal, wherein the collector terminals of the first and third transistors provide a first aspect of an output signal, and wherein the collector terminals of the second and fourth transistors provide a second aspect of the output signal.

17. The semiconductor device of claim 16, wherein the gain control circuit is coupled across a first control node between the base terminals of the first and fourth transistors and a second control node between the base terminals of the second and third transistors.

18. The semiconductor device of claim 17, wherein the gain control circuit comprises a first gain control transistor and a second gain control transistor that receive a first control current and a second control current respectively, wherein a base terminal of the first gain control transistor is coupled to the first control node, and wherein a base terminal of the second gain control transistor is coupled to the second control node.

19. The semiconductor device of claim 18, wherein the gain control circuit further comprises a current control subcircuit that generates the first control current and the second control current, wherein the current control subcircuit comprises a current source that feeds a differential pair of transistors, wherein a first transistor in the differential pair of transistors receives a variable voltage at a gate thereof, wherein the variable voltage sets a gain voltage for the gain control circuit, and wherein a second transistor in the differential pair of transistors receives a reference voltage at a gate thereof.

20. A system, comprising:
a gain block comprising cross-coupled differential pairs of transistors; and
a gain control circuit coupled with the cross-coupled differential pairs of transistors, wherein the gain control circuit provides an error compensation for a beta variation effect in the cross-coupled differential pairs of transistors.
